(19) United States
(12) Patent Application Publication
(10) Pub. No.: US 2015/0262927 A1
(43) Pub. Date: Sep. 17, 2015

(54) ELECTRONIC PACKAGE, PACKAGE CARRIER, AND METHODS OF MANUFACTURING ELECTRONIC PACKAGE AND PACKAGE CARRIER

(71) Applicant: ADL ENGINEERING INC., Hsin-Chu County (TW)

(72) Inventors: CHENG-YU KANG, Hsin-Chu county (TW); CHENG-HSIUNG YANG, Hsin-Chu county (TW); EN-MIN JOW, Hsin-Chu county (TW)

(21) Appl. No.: 14/621,744

(22) Filed: Feb. 13, 2015

Related U.S. Application Data
(60) Provisional application No. 61/939,306, filed on Feb. 13, 2014.
(60) Provisional application No. 62/095,224, filed on Dec. 22, 2014.
(60) Provisional application No. 62/095,229, filed on Dec. 22, 2014.

(51) Int. Cl. H01L 23/498; C25D 7/12; H05K 3/46; H05K 3/06; H01L 21/48; H05K 1/02

(52) U.S. Cl. CPC H01L 23/49811; H01L 23/49822; H01L 21/4853; H05K 1/0298; H05K 3/46; H05K 3/064; C25D 7/12; H01L 2021/60015

(57) ABSTRACT

A method of manufacturing package carrier is provided. In the method, a holding substrate and a conductive layer are provided. The conductive layer is on the holding substrate. Next, an insulating pattern is formed on the conductive layer. The insulating pattern exposes a portion of the conductive layer. A supporting board is provided. Next, the insulating pattern is detachably connected to the supporting board. After the insulating pattern is detachably connected to the supporting board, the holding substrate is removed, and the conductive layer remains. After removing the holding substrate, the conductive layer is patterned to form a wiring layer.

### BACKGROUND OF THE INVENTION

1. Field of the Invention

The present invention relates to an electronic package, a package carrier, and methods of manufacturing the electronic package and the package carrier.

2. Description of Related Art

During the general process of manufacturing semiconductor devices, after fine circuits are fabricated on the wafer, the wafer is diced into a plurality of dies. Afterwards, the dies are packaged and respectively mounted on the package carriers to form a plurality of electronic packages. In general, the above mentioned carrier has a structure which is similar to a printed circuit board (PCB). That is, the package carrier usually includes at least two wiring layers and at least one core layer interposed therebetween, and the core layer may be a cured prepreg. Accordingly, the conventional electronic package includes at least two wiring layers and at least one insulating layer (e.g. core layer) besides the die.

### SUMMARY OF THE INVENTION

The present invention provides a package carrier where at least one electronic component can be mounted.

The present invention provides an electronic package including the abovementioned package carrier.

The present invention provides methods of manufacturing the abovementioned package carrier and the electronic package.

According to an embodiment of the present invention, a method of manufacturing package carrier is provided. In the method, a holding substrate and a conductive layer formed thereon are provided. Next, an insulating pattern is formed on the conductive layer and exposes a portion of the conductive layer. In addition, a supporting board is provided, and the insulating pattern is in contact with and detachably connected to the supporting board. After the insulating pattern is detachably connected to the supporting board, the holding substrate is removed, and the conductive layer remains. After the holding substrate is removed, the conductive layer is patterned to form a wiring layer.

According to another embodiment of the present invention, a method of manufacturing package carrier is provided. In the method, a circuit structure and an insulating pattern are formed on a holding substrate. The insulating pattern is attached to the circuit structure, and the circuit structure is between the insulating pattern and the holding substrate. Then, a supporting board is provided. The supporting board is connected to and in contact with the insulating pattern. After the supporting board is connected to the insulating pattern, the holding substrate is removed, and the circuit structure remains.

According to an embodiment of the present invention, a package carrier is provided. The package carrier includes a circuit structure and an insulating pattern. The circuit structure includes at least one connecting pad and at least one mounting pad. The mounting pad is used for mounting an electronic component, and the connecting pad is used for electrically connecting the electronic component. The insulating pattern is connected to the circuit structure.

According to an embodiment of the present invention, the package carrier further includes a supporting board having a recess pattern. The recess pattern fits the insulating pattern. The insulating pattern is connected to the supporting board, where the insulating pattern is disposed in the recess pattern.

According to an embodiment of the present invention, an electronic package is provided. The electronic package includes the abovementioned carrier package, an electronic component and a molding layer. The electronic component is mounted on the mounting pad and electrically connected to at least one connecting pad. The mounting pad and the connecting pad are configured between the electronic component and the insulating pattern. The insulating pattern is disposed in the recess pattern.

According to another embodiment of the present invention, a method of manufacturing electronic package is provided. In the method, the electronic component is mounted on the mounting pad of the abovementioned package carrier including the supporting board. Afterwards, a molding layer covering the electronic component is formed on the circuit structure. After the molding layer is formed, the supporting board is removed.

Accordingly, the holding substrate and the supporting board are used to manufacture the package carrier. The package carrier and the electronic package without the core layer can be fabricated by the abovementioned manufacturing method, which is distinguishable over the conventional technique.

In order to further the understanding regarding the present invention, the following embodiments are provided along with illustrations to facilitate the disclosure of the present invention.

### BRIEF DESCRIPTION OF THE DRAWINGS

FIG. 1A to FIG. 2E respectively show sectional views of the package carrier in different steps of the manufacturing method provided in accordance with an embodiment of the present invention;

FIG. 3A to FIG. 3C respectively show sectional views of the electronic package in different steps of the manufacturing method provided in accordance with an embodiment of the present invention;

FIG. 4A and FIG. 4B respectively show sectional views of the package carrier in different steps of the manufacturing method provided in accordance with another embodiment of the present invention;

FIG. 5A and FIG. 5B respectively show sectional views of the electronic package in different steps of the manufacturing method provided in accordance with another embodiment of the present invention;

FIG. 6A to FIG. 6G respectively show sectional views of the package carrier in different steps of the manufacturing method provided in accordance with another embodiment of the present invention;

FIG. 7A to FIG. 7G respectively show sectional views of the package carrier in different steps of the manufacturing method provided in accordance with another embodiment of the present invention; and

FIG. 8A to FIG. 8E respectively show sectional views of the package carrier in different steps of the manufacturing method provided in accordance with another embodiment of the present invention.

### DETAILED DESCRIPTION OF THE EMBODIMENTS

The aforementioned illustrations and following detailed descriptions are exemplary for the purpose of further explaining the scope of the present invention. Other objectives and advantages related to the present invention will be illustrated in the subsequent descriptions and appended drawings.

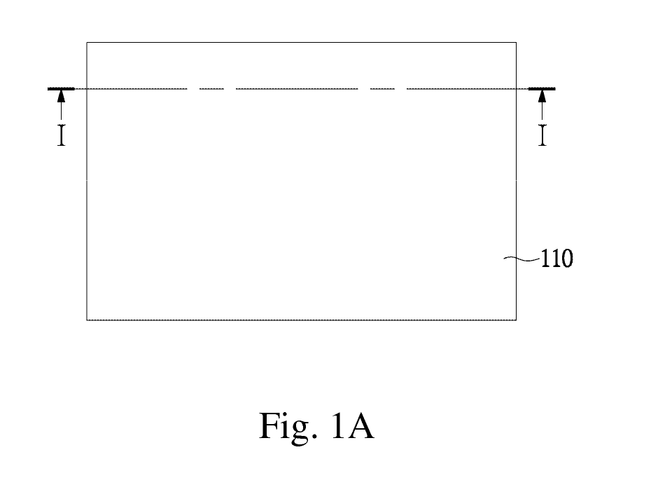

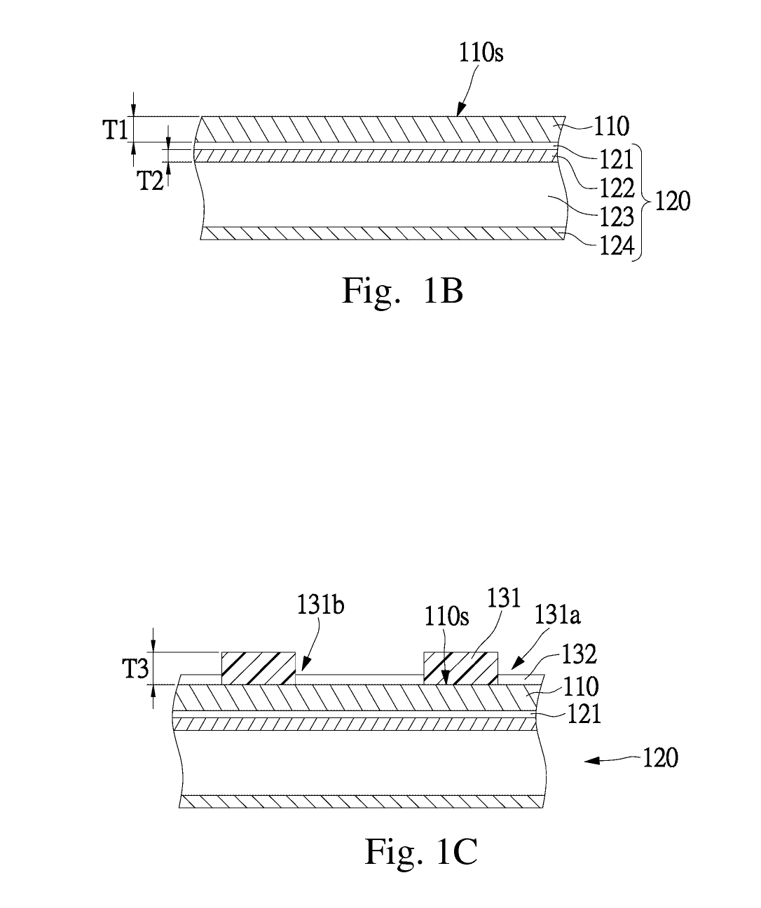

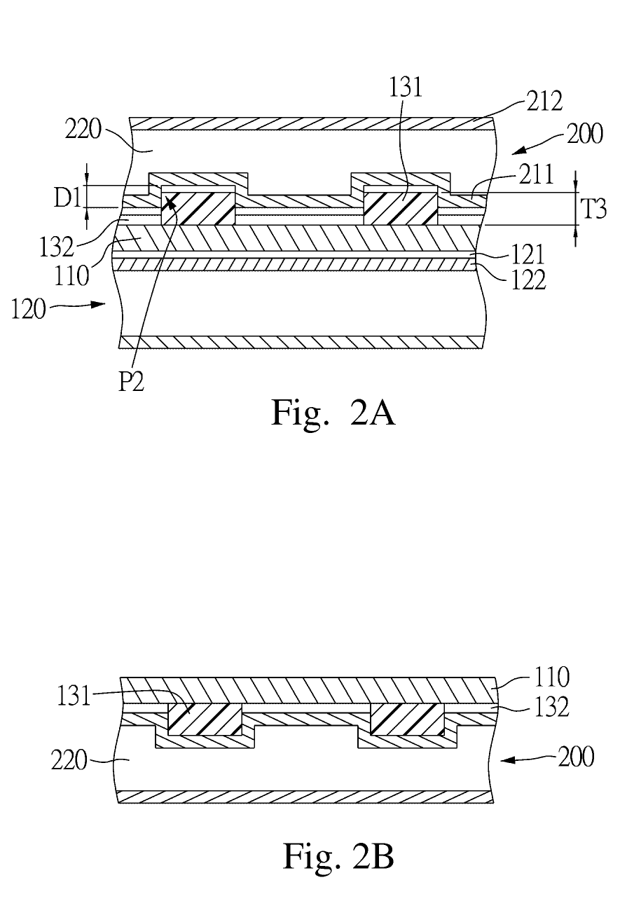

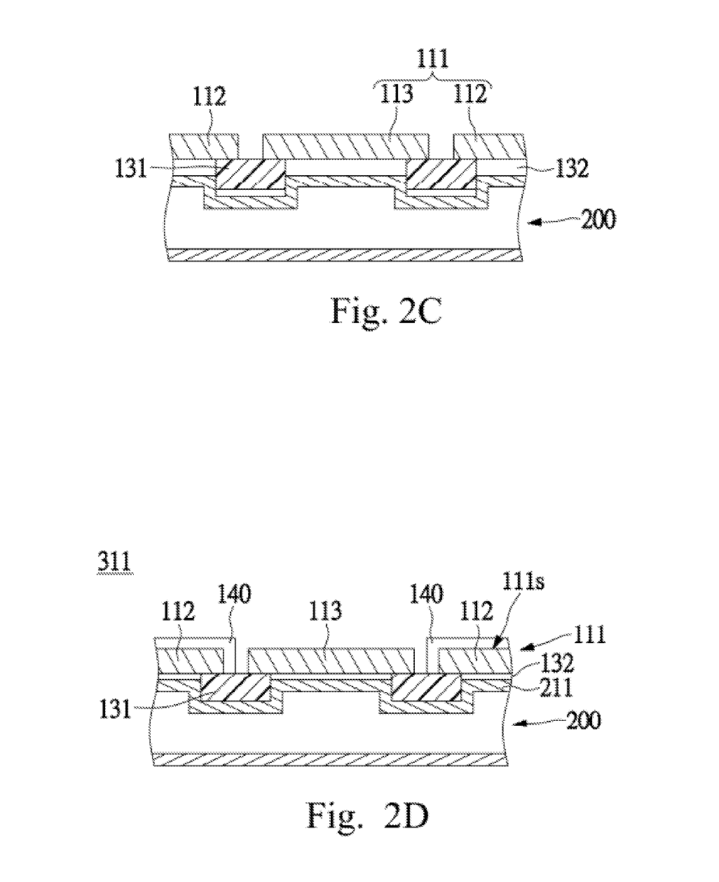

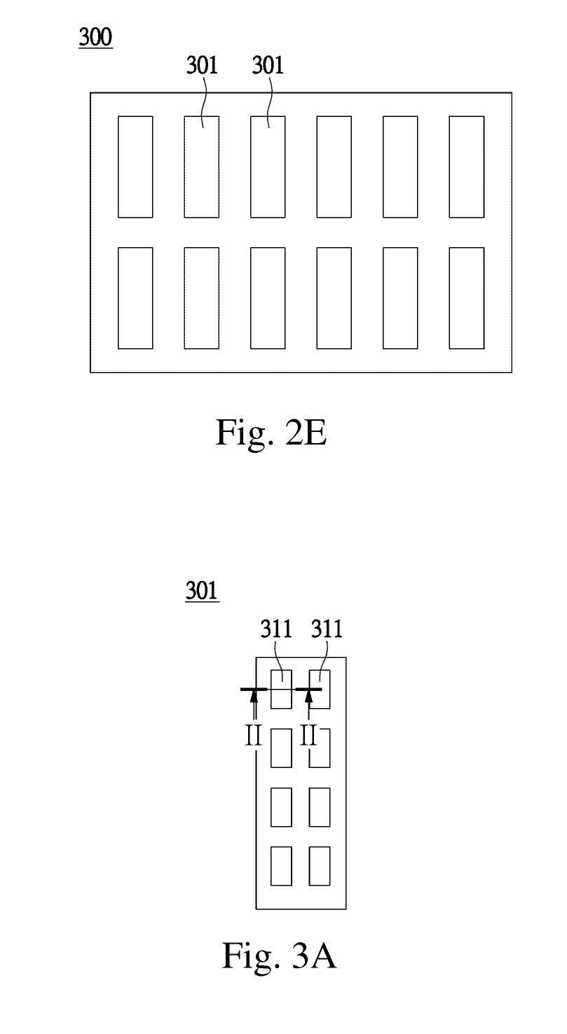

FIG. 1A to FIG. 2E respectively show sectional views of the package carrier in different steps of the manufacturing method provided in accordance with an embodiment of the present invention. FIG. 1A to FIG. 1C show the formation of the insulating pattern on the conductive layer. Please refer to FIG. 1A and FIG. 1B. FIG. 1B is a sectional view taken along a line I-I in FIG. 1A. In the method of manufacturing the package carrier according to the instant embodiment, a conductive layer 110 and a holding substrate 120 are provided. The conductive layer 110 is stacked on the holding substrate 120 and can be made of metal foil, such as a copper foil, a silver foil, an aluminum foil or an alloy foil.

The holding substrate 120 includes a main plate (not labeled) and a release layer 121, and the release layer 121 is interposed between the conductive layer 110 and the main plate. The main plate can be a ceramic plate, a metal plate, or a composite plate made of different kinds of materials. In the embodiment shown in FIG. 1B, the main plate is a composite plate and has multilayer. Specifically, the main plate includes a dielectric layer 123, two metal layers 122 and 124. The dielectric layer 123 is interposed between the two metal layers 122 and 124, and the release layer 121 is interposed between the metal layer 122 and the conductive layer 110.

The main plate can be a copper clad laminate (CCL), and the conductive layer 110 can be a metal foil, such as a copper foil, a silver foil, an aluminum foil, or an alloy foil. The dielectric layer 123 can be a cured prepreg, a resin layer and a ceramic layer. In addition, in the instant embodiment, the thickness T1 of the conductive layer 110 is larger than the thickness T2 of the metal layer 122. For example, the conductive layer 110 can be a copper foil having a thickness of 18 μm, and the metal layer 122 can be a copper foil having a thickness of 3 μm.

The conductive layer 110 can be connected to the holding substrate 120 through the release layer 121. However, the conductive layer 110 is adhered to the release layer 121 with a weak adhesion force so that the conductive layer 110 is easily separated from the release layer 121 when an enough external force is applied to the conductive layer 110. For example, the conductive layer 110 can be peeled off from the release layer 121 by hand. Additionally, the release layer 121 can be a metal sheet, such as an alloy sheet, or a polymer film.

Please refer to FIG. 1C. Subsequently, an insulating pattern 131 is formed on the conductive layer 110. The insulating pattern 131 has a thickness T3 ranging from 5 to 50 μm. The insulating pattern 131 locally covers the surface 110s of the conductive layer 110, and exposes a portion of the conductive layer 110. The insulating pattern 131 is attached to the conductive layer 110. Furthermore, the insulating pattern 131 has at least one opening formed therein. Taking FIG. 1C as an example, the insulating pattern 131 has two openings 131a and 131b, both of which extend to the surface 110s. The insulating pattern 131 can be a solder mask layer, such as a wet film solder mask or a dry film solder mask. In addition, the insulating pattern 131 may be formed by inkjet printing or lamination. Furthermore, the solder mask layer may be photosensitive, and openings 131a and 131b may be formed by exposure and development.

After the insulating pattern 131 is formed, a bonding material 132 is formed on the surface 110s of the conductive layer 110 which is exposed by the insulating pattern 131. The bonding material 132 can be a solder layer, metallic layer or organic solderability preservatives (OSP) layer. The solder is, for example, tin paste, silver glue or copper paste, and the metallic layer is, for example, a nickel layer, a gold layer, a silver layer, a palladium layer, a Ni/Au layer, or a Ni/Pd/Au layer, in which both the Ni/Au layer and the Ni/Pd/Au layer are multilayer films

The solder may be formed by applying or dispensing, and the metallic layer may be formed by deposition, such as chemical vapor deposition (CVD), physical vapor deposition (PVD), electroplating or electroless plating. The physical vapor deposition is, for example, evaporation or sputtering. The OSP layer may be formed by dipping.

FIG. 2A to FIG. 2D show the method of manufacturing the wiring layer of the package carrier according to the instant embodiment. Please refer to FIG. 2A. The supporting board 200 is provided. The supporting board 200 illustrated in may include a plastic board 220 and two metal layers 211 and 212. The metal layers 211 and 212 each may be a metal foil, such as cooper foil, silver foil or alloy foil. The metal layer 211 has a recess pattern P2. The recess pattern P2 can be formed by pressing, lithography, casting, or electroplating etc. Afterwards, the insulating pattern 131 is detachably connected to the supporting board 200, so that the conductive layer 110, the holding substrate 120, the insulating pattern 131, and the supporting board 200 can be connected together. The method of detachably connecting the insulating pattern 131 to the supporting board 200 can include pressing the holding substrate 120 to the supporting board 200.

After the insulating pattern 131 is detachably connected to the supporting board 200, the insulating pattern 131 is in contact with the supporting board 200 and disposed in the recess pattern P2. Meanwhile, the metal layer 211 is interposed between the insulating pattern 131 and the plastic board 220, as shown in FIG. 2A. The recess pattern P2 can fit the insulating pattern 131 so that the insulating pattern 131 can be fixed in the recess pattern P2. In addition, the thickness T3 of the insulating pattern 131 can be greater than or equal to a depth D1 of the recess pattern P2. In another case, the thickness T3 can be less than the depth D1 of the recess pattern P2.

In the instant embodiment, the insulating pattern 131 can be fixed in the recess pattern P2 by adhering. For example, during the step of pressing, both the supporting board 200 and the insulating pattern 131 can be heated to soften the insulating pattern 131 and generate adhesive ability. Hence, the insulating pattern 131 can adhere to the supporting board 200 and be fixed in the recess pattern P2. In addition, except the insulating pattern 131, the other adhesive materials can make the supporting board 200 adhere to the insulating pattern 131. The adhesive material can be a reusable pressure sensitive adhesive, such as a rubber-based pressure sensitive adhesive, acrylic-based pressure sensitive adhesive or silicone resin-based pressure sensitive adhesive. In addition, the adhesive material may be made of silicone resin, rubber, polydimethylsiloxane (PDMS), polymethylmethacrylate (PMMA, or acrylic) or resin.

In addition, the supporting board 200 illustrated in FIG. 2A is a composite board having a multilayered structure and including the plastic board 220 and two metal layers 211 and 212. However, in another embodiment, the supporting board may be a ceramic board, a metal board, a thermoplastic board, or a composite board without the multilayered structure. The thermoplastic board is, for example, a polymethacrylate board, i.e., an acrylic board. The metal board can be made of a single metal material or an alloy material. Thus, the supporting board 200 is not limited to the composite board as shown in FIG. 2A.

Please refer to FIG. 2A and FIG. 2B. After the insulating pattern 131 is detachably connected to the supporting board 200, the holding substrate 120 is removed and the conductive layer 110 remains on the supporting board 200 without being covered. There are many ways of removing the holding substrate 120. In the instant embodiment, the holding substrate 120 can be removed from the conductive layer 110 by peeling off the release layer 121 with hand or machine. In addition, in another embodiment, when the holding substrate 120 is a metal plate, the holding substrate 120 can be removed by etching. Accordingly, the means of removing the holding substrate 120 is not limited to peeling.

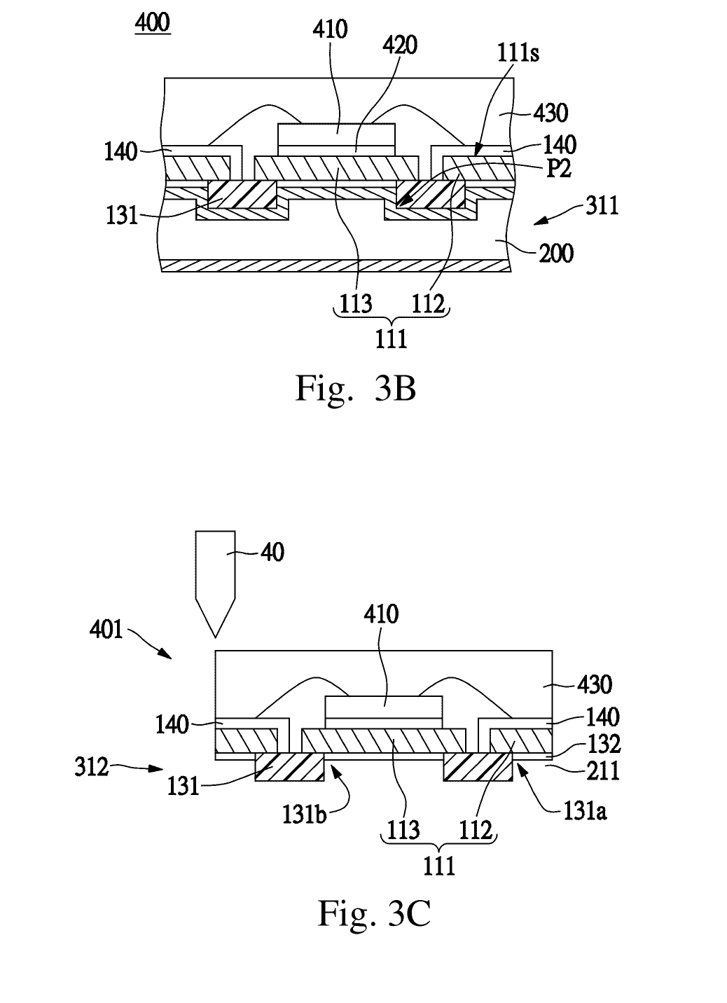

Please refer to FIG. 2B and FIG. 2C. Subsequently, the conductive layer 110 is patterned to form a wiring layer 111, which is a circuit structure. The wiring layer 111 can be formed by photolithography and etching (i.e. lithography). The wiring layer 111 includes at least one connecting pad 112 and at least one mounting pad 113. The mounting pad 113 is used for mounting an electronic component 410 (please refer to FIG. 3B), and the connecting pad 112 is used for electrically connecting the electronic component 410. Additionally, only one mounting pad 113 and two connecting pads 112 are shown in FIG. 2C. In another embodiment, the number of the mounting pads 113 may be a plurality, and the number of the connecting pads 112 may be one, three or larger than three. Accordingly, both the numbers of the mounting pads 113 and the connecting pads 112 are not limited to the number shown in FIG. 2C.

Please refer to FIG. 2D. After the formation of the wiring layer 111, the surface roughness of the wiring layer 111 can be changed. Specifically, according to the demands of the product, a surface treatment, such as roughening or polishing treatment, can be performed to the surface 111s of the wiring layer 111 so that the roughness of the surface 111s satisfies the demands of the product. The roughening treatment can be a black oxide treatment or a brown oxide treatment, which are usually applied in the manufacturing of PCB. After the roughening treatment is performed on the wiring layer 111, a rough oxide layer, such as a copper oxide layer, is formed on the surface 111s. Thus, the surface roughness of the surface 111s can be increased.

The polishing treatment can be a brushing or electropolishing treatment. After the conductive layer 110 is polished, the surface roughness of the surface 110s is decreased. In addition, a rough oxide layer, such as a copper oxide layer, can be pre-formed on the surface 111s of the wiring layer 111. The abovementioned surface treatment, such as a brushing treatment, laser treatment or plasma etching treatment can be performed to remove a portion of rough oxide layer to decrease the surface roughness of the surface 111s.

After the surface roughness of the wiring layer 111 is changed, a protective layer 140 can be formed on the wiring layer 111. At this time, a package carrier 311 including the supporting board 200, the wiring layer 111, the insulating pattern 131 stacked on and connected to the wiring layer 111, the bonding material 132 and protective layer 140 is basically completed. The material of the protective layer 140 may be the same as the bonding material 132. That is to say, the protective layer 140 can be a solder layer, metallic layer or organic solderability preservatives (OSP) layer. It is noted that, in the instant embodiment, the method of manufacturing the package carrier includes the steps of changing the surface roughness of the wiring layer 111 and forming the protective layer 140. However, in another embodiment, the abovementioned two steps can be omitted. In this case, the package carrier 311 may not include the protective layer 140.

Please refer to FIG. 2E, which shows the top view of FIG. 2D. In the instant embodiment, a plurality of the package carriers 311 is directly formed on the working panel, which can be call “panel”, 300. Specifically, the working panel 300 includes a plurality of strips 301, and each of the strips 301 may include one or more package carriers 311. After the process shown in FIG. 2D finish, a plurality of package carriers 311 can be formed on the strips 301 during the same process. Please refer to FIG. 2D and FIG. 2E. Subsequently, the supporting board 200, the insulating pattern 131, and the wiring layer 111 are all diced to divide the working panel 300 into the strips 301.

FIG. 3A to FIG. 3C respectively show sectional views of the electronic package in different steps of the manufacturing method provided in accordance with an embodiment of the present invention. Please refer to FIG. 3A and FIG. 3B. FIG. 3B is a sectional view taken along a line II-II in FIG. 3A. After the working panel 300 is diced to form the plurality of strips 301, one or multiple electronic components 410 are mounted on one of the strips 301. The electronic component 410 can be mounted on the strip 301 by wire bonding or flip chip. The electronic component 410 can be a die or a discrete component. The electronic component 410 is mounted on the mounting pad 113, and the wiring layer 111 is interposed between the electronic component 410 and the insulating pattern 131.

Subsequently, a molding layer 430 covering the wiring layer 111 and the electronic component 410 is formed on the wiring layer 111. Furthermore, the molding layer 430 encapsulates the electronic component 410. So far, an electronic package 400 including the package carrier 311, the electronic component 410 and the molding layer 430 is basically completed.

In the embodiment shown in FIG. 3B, the electronic component 410 is mounted on the strip 301 by wire bonding, and attached on the mounting pad 113 by an adhesive layer 420. The adhesive layer 420 can be silver glue or polymer glue. When the adhesive layer 420 is silver glue, the adhesive layer 420 may diffuse due to the surface roughness of the mounting pad 113. However, because the surface roughness of the surface 111s of the wiring layer 111 can be changed by performing a surface treatment, the diffusion of the adhesive layer 420 can be attenuated. Thus, the electronic component 410 can be firmly attached on the mounting pad 113. For similar reasons, the bonding force between the molding layer 430 and the wiring layer 111 is related to the surface roughness of the surface 111s. Accordingly, the bonding force between the molding layer 430 and the wiring layer 111 can be improved by performing the abovementioned surface treatment on the wiring layer 111 to prevent the molding layer 430 from leaving.

Please refer to FIG. 3B and FIG. 3C. Subsequently, the insulating pattern 131 is detached from the recess pattern P2 to separate the supporting board 200 from the insulating pattern 131. Specifically, the bonding force between the supporting board 200 and the insulating pattern 131 is weaker or much less than that between the insulating pattern 131 and the wiring layer 111. Hence, enough external force can be applied to the supporting board 200 by hand or machine to separate the supporting board 200 from the insulating pattern 131.

After the supporting board 200 and the insulating pattern 131 are separated from each other, the insulating pattern 131 is exposed. The opening 131a is aligned to the connecting pad 112, and the opening 131b is aligned to the mounting pad 113. In addition, the bonding material 132 exposed by the opening 131a can be used to connect the solder, such as tin balls, and the bonding material 132 exposed by the opening 131b can be used to connect the heat sink to assist the heat dissipation of the electronic component 410. Thereafter, the strip 301 (please refer to FIG. 3A) is diced by a cutting tool 40 to form the electronic package 401 and the package carrier 312 both without the supporting boards 200.

Notably, in another embodiment, each strip 301 may be a package carrier 311. That is, the working panel 300 (please refer to FIG. 2E) can be directly diced to form the package carriers 311 each having a supporting board 200. Accordingly, after the arrangement of the electronic component 410 and the formation of the molding layer 430 are completed, there is no need for dicing the strips 301. In addition, the supporting board 200 can be kept so that the electronic package 401 with the supporting board 200 can be shipping.

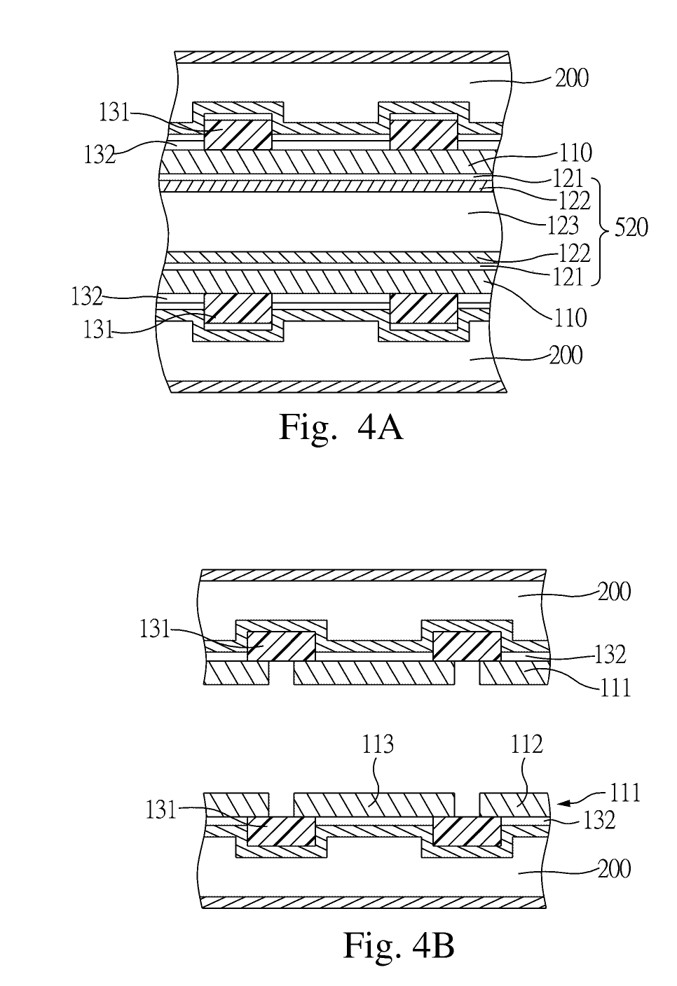

FIG. 4A and FIG. 4B respectively show sectional views of the package carrier in different steps of the manufacturing method provided in accordance with another embodiment of the present invention. This embodiment is similar to the abovementioned embodiment. For example, the method of the embodiment includes the process as described by the abovementioned embodiment. The following mainly describes the difference between this embodiment and the abovementioned embodiment and does not describe the sameness of both embodiments again.

Referring to FIG. 4A, firstly, the holding substrate 520 and at least two conductive layer 110 are provided. The conductive layers 110 are disposed on the holding substrate 520. The holding substrate 520 is interposed between the conductive layers 110. Basically, the holding substrate 520 is similar to the holding substrate 120. The holding substrate 520 also includes the release layer 121, the dielectric layer 123, and the metal layer 122

However, compared with the holding substrate 120, the holding substrate 520 includes two release layer 121 for disposing the conductive layer 110. Although the holding substrate 520 in FIG. 4A includes no metal layer 124, the metal layer 122 in FIG. 4A is substantially the same as the metal layer 124. The difference between the metal layers 122 and 124 is merely whether the release layer 121 covers. Moreover, both the dielectric layer 123 and the metal layer 122 of the holding substrate 520 can be replaced by a ceramic plate or a metal plate.

Next, two insulating pattern 131 are formed on the conductive layer 110 respectively. Then, the bonding material 132 can be formed on the portion of conductive layer 110 exposed by the insulating pattern 131. Two supporting board 200 are provided, and the insulating patterns 131 are detachably connected to the supporting boards 200 respectively. The insulating pattern 131 is in contact with the supporting board 200. Next, the holding substrate 520 is removed, and the conductive layers 110 remain. Removing the holding substrate 520 is the same as removing the holding substrate 120 and not described again.

Referring to FIG. 4A and FIG. 4B, the conductive layers 110 are patterned to form at least two wiring layers 111 after removing the holding substrate 520. So far, two package carriers are basically complete, as shown in FIG. 4B. A plurality of electronic component 410 can be mounted the mounting pads 113 of the package carriers respectively, as shown in FIG. 3B and FIG. 3C. Furthermore, the processes as disclosed in FIG. 2D can be performed to the package carriers after forming the wiring layers 111. For example, the surface roughness of the wiring layers 111 can be changed, and the protective layer 140 can be formed on the wiring layer 111 (as shown in FIG. 2D).

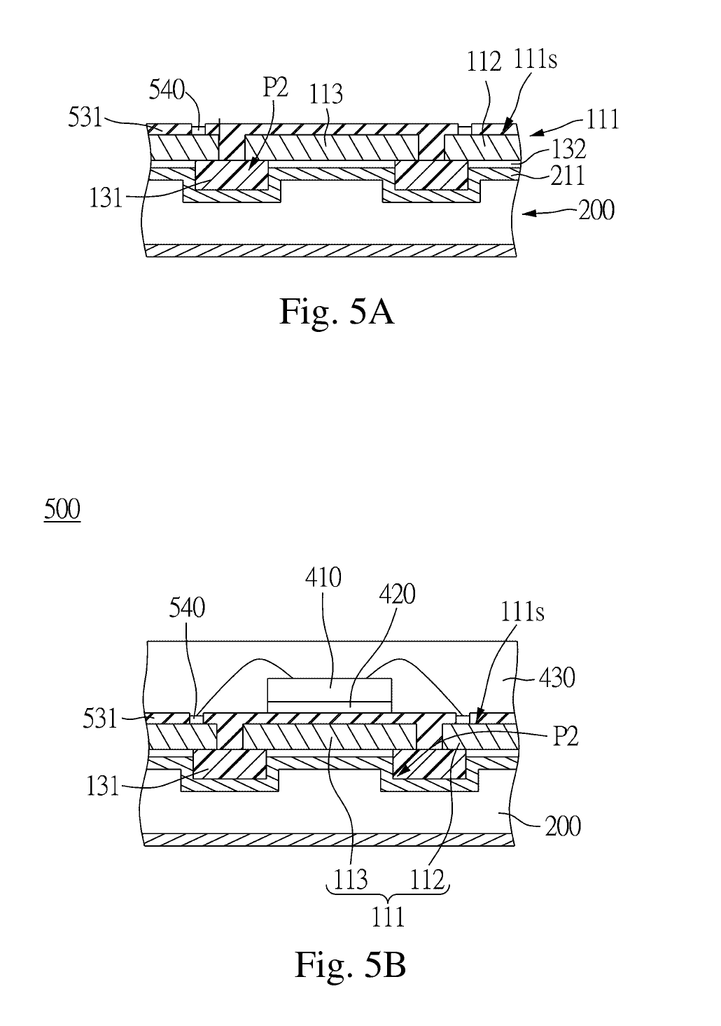

FIG. 5A and FIG. 5B respectively show sectional views of the electronic package in different steps of the manufacturing method provided in accordance with another embodiment of the present invention. This embodiment is similar to the abovementioned embodiment as described in FIG. 1A to FIG. 2E. For example, the method of manufacturing according to the embodiment also includes the abovementioned processes disclosed in FIG. 1A to FIG. 2C. However, it is different from the processes disclosed in FIG. 2D that the method of the embodiment does not include the formation of the protective layer 140, but includes the formation of a solder mask layer 531.

Referring to FIG. 5A, the solder mask layer 531 is formed on the surface 111s of the wiring layer 111 and exposes the wiring layer 111 after forming the wiring layer 111. Forming the solder mask layer 531 can be the same as forming insulating pattern 131. The solder mask layer 531 partially covers the wiring layer 111. The solder mask layer 531 can entirely cover the mounting pad 113 and expose a portion of the connecting pad 112, as shown in FIG. 5A.

A protective layer 540 can be formed on the surface 111s which is not covered by the solder mask layer 531 after forming the solder mask layer 531. The protective layer 540 may be a metal layer, such as a nickel layer, a gold layer, a silver layer, a palladium layer, a Ni/Au layer, or a Ni/Pd/Au layer. The protective layer 540 can help the wiring layer 111 to prevent oxidizing. Moreover, the protective layer 540 can be formed by electroplating.

Specifically, after the insulating pattern 131 is detachably connected to supporting board 200, the metal layer 211 having the recess pattern P2 can be electrically connected to the wiring layer 111. For example, in the condition that the bonding material 132 is a solder or a metal layer, the metal layer 211 can touch the bonding material 132 so that the metal layer 211 is electrically connected to the wiring layer 111 through the bonding material 132. Moreover, the metal layer 211 can touch the wiring layer 111 directly without bonding material 132, thereby electrically connecting the metal layer 211 to the wiring layer 111. Afterwards, the electroplating is performed. During the electroplating, electrifying the metal layer 211 can electroplate the wiring layer 111 due to the electrical connection between the metal layer 211 and the wiring layer 111. Thus, the protective layer 540 exposed by the solder mask layer 531 is formed on the wiring layer 111.

In the traditional electroplating process of PCB, a plating bar is usually formed on a working panel. The plating bar is electrically connected to the wiring layers of all the strips so that the wiring layers of the strips can be electrically connected to each other, thereby electroplating the wiring layers to form the protective layers. Accordingly, after forming the protective layer, the plating bar has to be removed or cut to prevent short circuit.

The embodiment uses the metal layer 211 of the supporting board 200 for electroplating, thereby forming the protective layer 540. It is different from the traditional electroplating process of PCB that the embodiment does not need the plating bar to perform electroplating for formation of the protective layer 540. Thus, the method of manufacturing according the embodiment can omit the plating bar to increase the region for making the wiring of the working panel, thereby manufacturing more package carriers from one working panel.

Referring to FIG. 5B, after the solder mask layer 531 and the protective layer 540 are formed, the process as described in FIG. 3B can be performed. That is, at least one electronic component 410 can be mounted on the mounting pad 113 via the adhesive layer 420. The electronic component 410 can be mounted by wire bonding or flip chip and electrically connected to the protective layer 540. Next, the molding layer 430 encapsulating the electronic component 410 is formed on the solder mask layer 531. So far, an electronic package 500 including the solder mask layer 531, the protective layer 540, the electronic component 410, and the molding layer 430 is basically complete. In addition, after the molding layer 430 is formed, the process as described in FIG. 3C can be performed. That is, the supporting board 200 is separated from the insulating pattern 131. Thus, the supporting board 200 can be removed, and the dicing is performed to form an electronic package 500 without the supporting board 200.

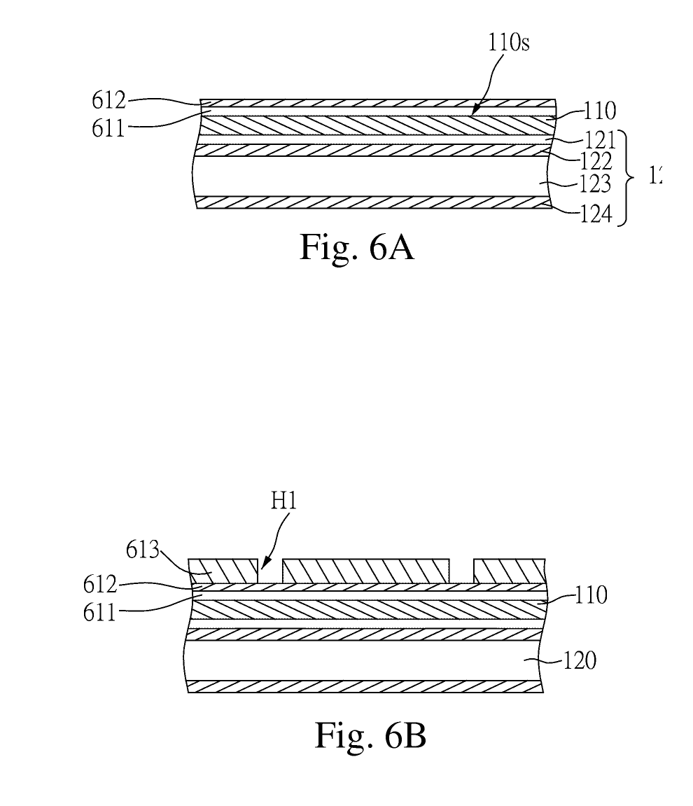

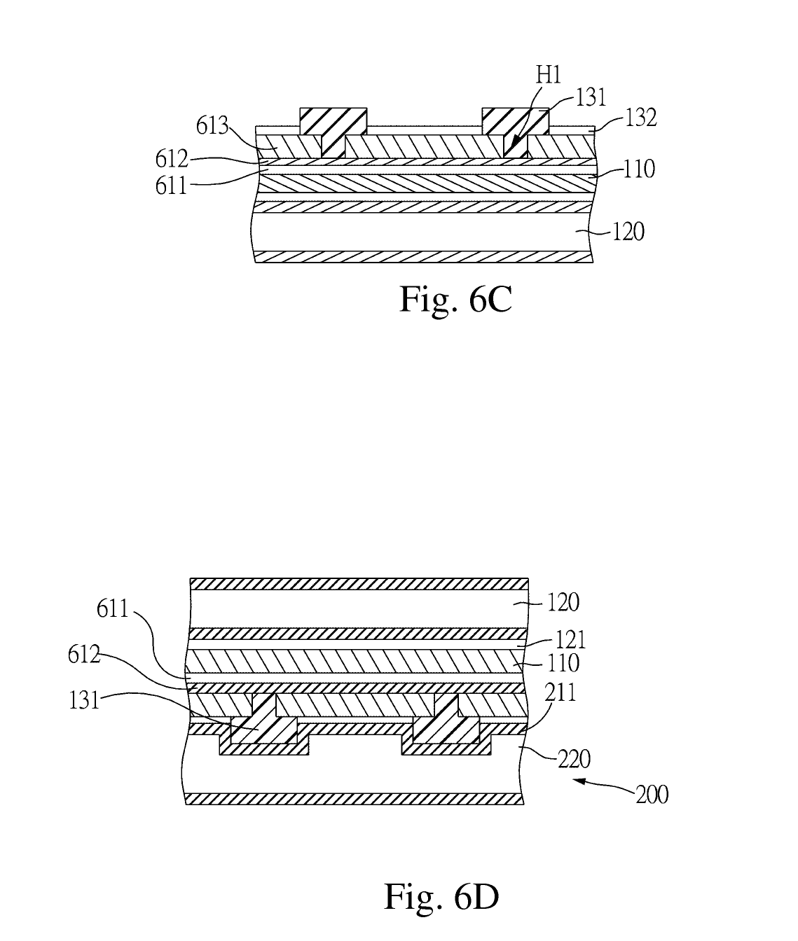

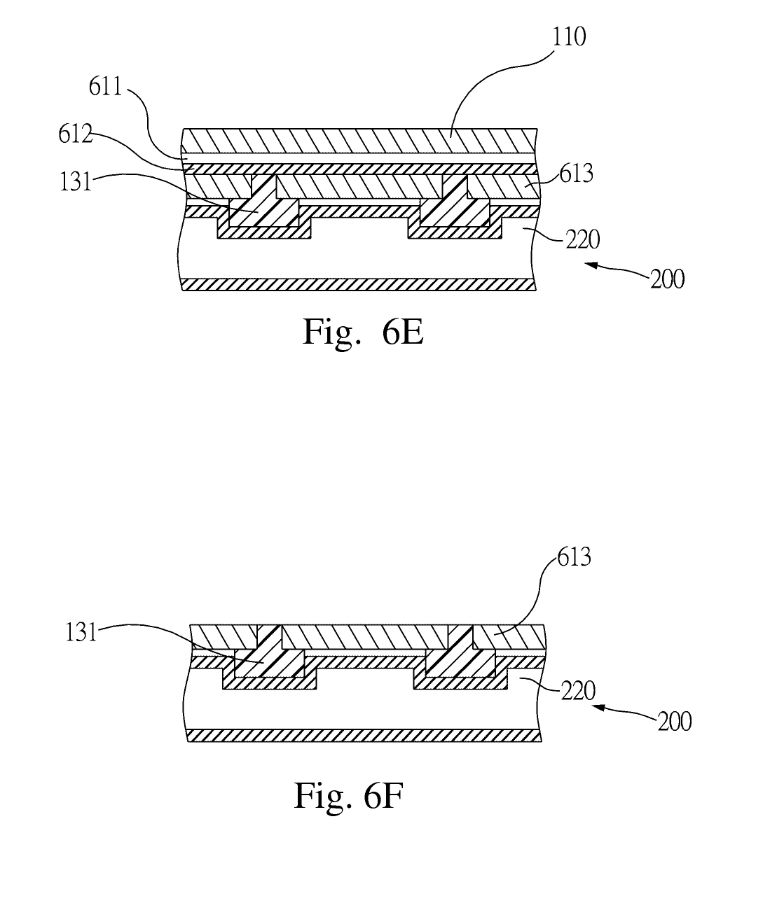

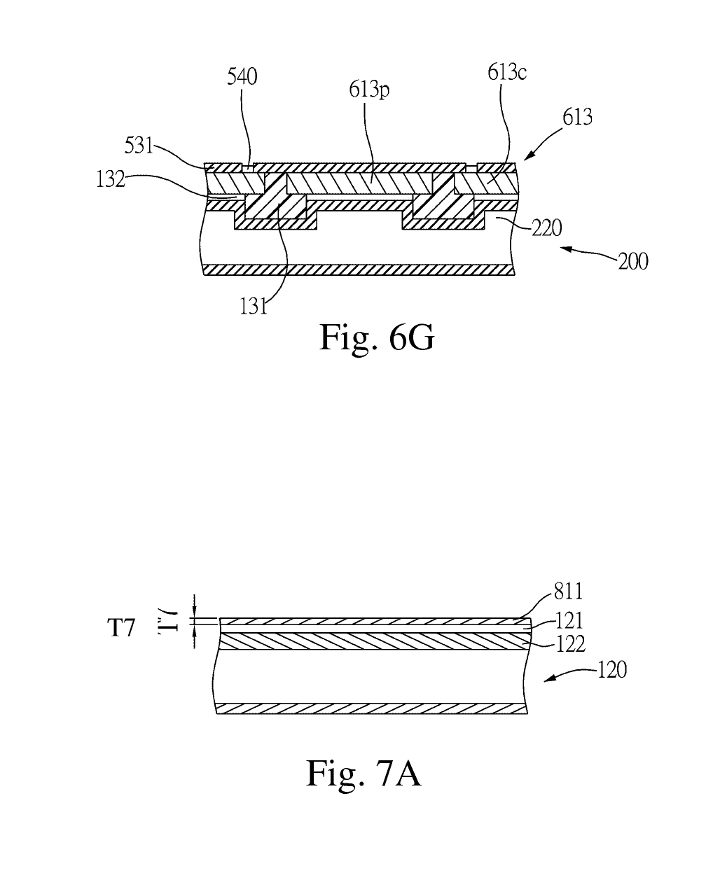

FIG. 6A to FIG. 6G respectively show sectional views of the package carrier in different steps of the manufacturing method provided in accordance with another embodiment of the present invention. This embodiment is similar to the abovementioned embodiments. For example, the method of manufacturing according to the embodiment also uses the conductive layer 110 and the holding substrate 120 and includes the formations of the insulating pattern 131, the solder mask layer 531, and the protective layer 540. The following mainly describes the difference between this embodiment and the abovementioned embodiments and does not describe the sameness again.

Referring to FIG. 6A, firstly, a holding substrate 120 and a conductive layer 110 disposed on the holding substrate 120 are provided, and a barrier layer 611 is formed on the surface 110s of the conductive layer 110. Then, a seed layer 612 is formed on the barrier layer 611 which is interposed between the conductive layer 110 and the seed layer 612. The barrier layer 611 and the seed layer 612 both may be metal layers, and the material of the barrier layer 611 is different from the materials of the conductive layer 110 and the seed layer 612. For example, the barrier layer 611 may be a nickel layer, whereas the conductive layer 110 and the seed layer 612 may be copper layers. In addition, forming the barrier layer 611 and the seed layer 612 can be deposition, such as CVD, PVD, electroplating or electroless plating.

Referring to FIG. 6B, next, at least one wiring layer 613 is formed on the seed layer 612, and the wiring layer 613 is a circuit structure and has at least one opening H1. The wiring layer 613 can be formed by electroplating. During the electroplating, the seed layer 612 and the barrier layer 611 are be electrified, there performing the deposition on the seed layer 612.

The wiring layer 613 can be formed by additive method or subtractive method. When the wiring layer 613 is formed by additive method, it can use a developed dry film or a developed photoresist as a mask and perform electroplating to form the wiring layer 613 directly on the seed layer 612. When the wiring layer 613 is formed by subtractive method, the seed layer 612 can become thicker by electroplating at first. Then, the lithography is performed to the thicker seed layer 612 to form the wiring layer 613.

It is noted that the barrier layer 611 can also be use as a seed layer for electroplating because the barrier layer 611 is the metal layer. Thus, in another embodiment, the wiring layer 613 can be formed by electroplating with barrier layer 611 and no seed layer 612.

Referring to FIG. 6C, next, the insulating pattern 131 is formed on the wiring layer 613. The insulating pattern 131 fills the opening H1 and touches the seed layer 612. Afterwards, the bonding material 132 can be formed on the portion of the wiring layer 613 exposed by the insulating pattern 131.

Referring to FIG. 6D, next, the supporting board 200 is provided. The insulating pattern 131 in contact with the supporting board 200 is detachably connected to the supporting board 200. The metal layer 211 has the recess pattern (not labeled) fitting the insulating pattern 131 which is disposed in the recess pattern. Detachably connecting the insulating pattern 131 to the supporting board 200 is the same as abovementioned embodiments and does not be described again.

Referring to FIG. 6D and FIG. 6E, after the insulating pattern 131 is detachably connected to the supporting board 200, the holding substrate 120 is removed, and the wiring layer 613 remains. At this time, the conductive layer 110 is exposed. Referring to FIG. 6E and FIG. 6F, next, the conductive layer 110, the barrier layer 611, and the seed layer 612 are removed. Removing these films can be wet etching. Since the material of the barrier layer 611 is different from the material of the conductive layer 110, the etchant for removing the barrier layer 611 is different from the etchant for removing the conductive layer 110. For example, an acid etchant can remove the barrier layer 611 (e.g. nickel layer), whereas a base etchant can remove the conductive layer 110 (e.g. copper layer).

Referring to FIG. 6G, next, the solder mask layer 531 and the protective layer 540 are formed on the wiring layer 613 which includes a connecting pad 613c and the mounting pad 613p. The solder mask layer 531 can entirely cover the mounting pad 613p and expose the portion of the connecting pad 613c, as shown in FIG. 6G.

After the insulating pattern 131 is detachably connected to the supporting board 200, the metal layer 211 is electrically connected to the wiring layer 613. For example, the metal layer 211 can be electrically connected to the wiring layer 613 through the bonding material 132. Alternatively, the metal layer 211 can directly touch the wiring layer 613 to electrically connect the metal layer 211 to the wiring layer 613. Thus, during the electroplating, the current can flow to the wiring layer 613 through the metal layer 211 by the electrical connection between the metal layer 211 and the wiring layer 613 so that the protective layer 540 can be formed on the wiring layer 613. Furthermore, the wiring layer 613 may have at least one electroplating clamp point.

Notably, after the solder mask layer 531 and the protective layer 540 are formed, the process as described in FIG. 3B can be performed. That is, at least one electronic component is mounted on the mounting pad 613p and electrically connected to the connecting pad 613c. Next, the molding layer encapsulating the electronic component is formed on the solder mask layer 531. Moreover, after forming the molding layer, the process as described in FIG. 3C can be performed. That is, the supporting board 200 is removed and the dicing is performed to form an electronic package without the supporting board 200.

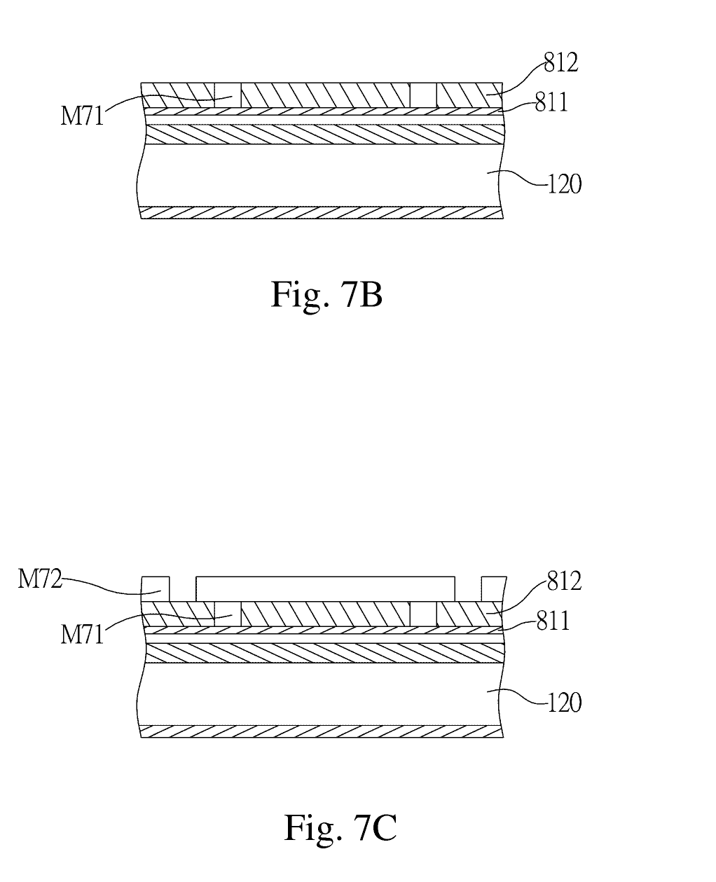

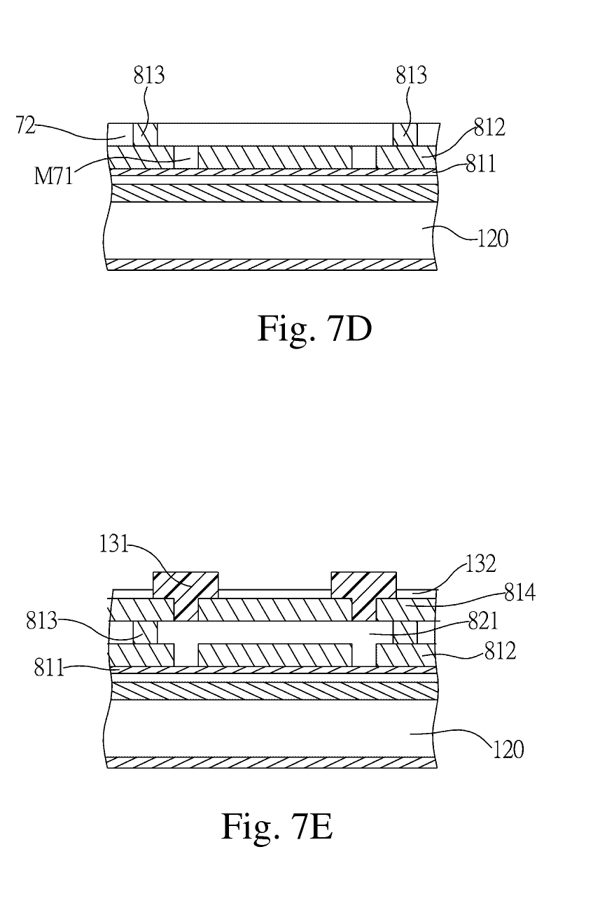

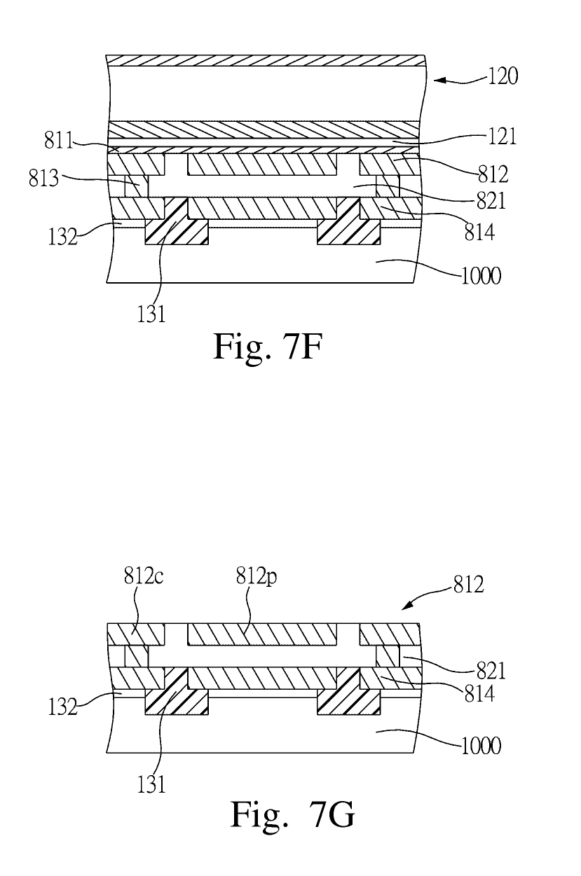

FIG. 7A to FIG. 7G respectively show sectional views of the package carrier in different steps of the manufacturing method provided in accordance with another embodiment of the present invention. This embodiment is similar to the abovementioned embodiment. For example, the method of manufacturing according to the embodiment also uses the holding substrate 120 and includes the formation of the insulating pattern 131. The following mainly describes the difference between this embodiment and the abovementioned embodiment and doesn't describe and illustrate the sameness of both embodiments again.

Referring to FIG. 7A, firstly, the conductive layer 811 and the holding substrate 120 are provided. The conductive layer 811 is stacked on the holding substrate 120 and disposed on the release layer 121. The release layer 121 is interposed between the conductive layer 811 and the metal layer 122. The conductive layer 811 may be a metal foil, such as a copper foil, a silver foil, an aluminum foil or an alloy foil. The thickness T7 of conductive layer 811 may be less than the thickness of the conductive layer 110. The thickness T7 may be 3 μm.

Referring to FIG. 7B, next, a first wiring layer 812 is formed on the holding substrate 120. The first wiring layer 812 is formed by additive method. Specifically, forming the first wiring layer 812 includes a first patterned mask M71 is formed on the conductive layer 811. The first patterned mask M71 is such as a developed dry film or a developed photoresist as a mask. Next, electroplating is performed by using the conductive layer 811 as a seed layer, so that the first wiring layer 812 is formed on the surface of the conductive layer 811 which is not covered by the first patterned mask M71.

Referring to FIG. 7C and FIG. 7D, next, a plurality of metal posts 813 is formed on the first wiring layer 812. The metal posts 813 can be formed by photolithography and deposition. In detail, after forming the first wiring layer 812, the first patterned mask M71 remains, and a second patterned mask M72 is formed on the first patterned mask M71 and the first wiring layer 812. The second patterned mask M72, such as a developed dry film or a developed photoresist, covers and is in contact with both the first patterned mask M71 and the first wiring layer 812.

Afterwards, a deposition is performed to form the metal posts 813 on the first wiring layer 812. The deposition may be electroplating. During forming the metal posts 813, the first wiring layer 812 can be electrically connected to the conductive layer 811. Thus, the first wiring layer 812 can be used as a seed layer for electroplating to form the metal posts 813.

Referring to FIG. 7E, after forming the metal posts 813, the first patterned mask M71 and the second patterned mask M72 are removed. Next, a dielectric layer 821, such as a cured prepreg or resin, covering the first wiring layer 812 and the metal posts 813 is formed. The dielectric layer 821 can be formed by applying or laminating. After forming the dielectric layer 821, the dielectric layer 821 is grinded so that the ends of the metal posts 813 are exposed.

Next, a second wiring layer 814 connected to the metal posts 813 is formed on the dielectric layer 821 so that the metal posts 813 are electrically connected to the first wiring layer 812 and the second wiring layer 814. The second wiring layer 814 can be formed by additive method or subtractive method. In addition, the second wiring layer 814 and the metal post 813 can be formed by build-up method. So far, a circuit structure including two wiring layers (i.e. the first wiring layer 812 and the second wiring layer 814), a dielectric layer 821 interposed between the wiring layer, and a plurality of metal posts 813 arranged in the dielectric layer 821 is formed on the holding substrate 120.

It is noted that the circuit structure in FIG. 7E includes two wiring layers. However, in another embodiment, the circuit structure may include at least three wiring layers and at least two dielectric layers 821. In other words, a wiring layer, a dielectric layer 821 and metal posts 813 may be formed on the second wiring layer 814. Hence, the method as shown in FIG. 7A to FIG. 7E can manufacture a circuit structure including at least three wiring layers. In addition, after the circuit structure is formed, the insulating pattern 131 and the bonding material 132 can be formed on the second wiring layer 814 in sequence.

Referring to FIG. 7F, then, a supporting board 1000 is provided, and the insulating pattern 131 in contact with the supporting board 1000 is detachably connected to the supporting board 1000. The supporting board 1000 may be the supporting board 200 or other suitable supporting board so that the supporting board 1000 also has the recess pattern (not labeled) fitting the insulating pattern 131.

Referring to FIG. 7F and FIG. 7G, next, the holding substrate 120 and the conductive layer 811 are removed. Removing the conductive layer 811 can be wet etching. Afterwards, the solder mask layer 531 and the protective layer 540 both as shown in FIG. 5A can be formed on the first wiring layer 812. Alternatively, the protective layer 140 as shown in FIG. 2D can be formed on the first wiring layer 812.

Next, the process as described in FIG. 3B can be performed. That is, at least one electronic component can be mounted on the mounting pad 812p of the first wiring layer 812 and electrically connected to the connecting pad 812c of the first wiring layer 812. Then, a molding layer encapsulating the electronic component is provided. After forming the molding layer, the process as described in FIG. 3C. That is, the supporting board 1000 is removed, and the dicing is performed to form an electronic package without the supporting board 1000.

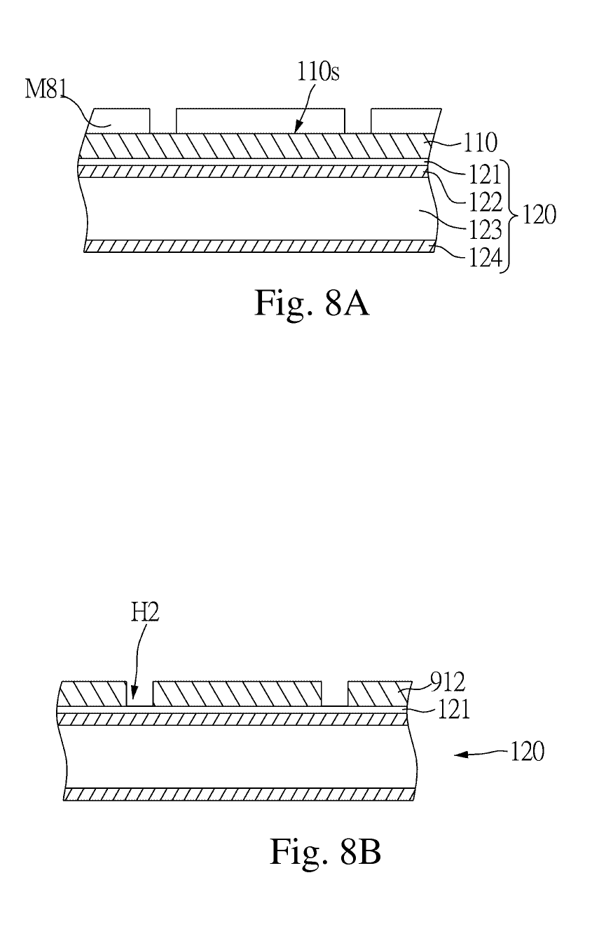

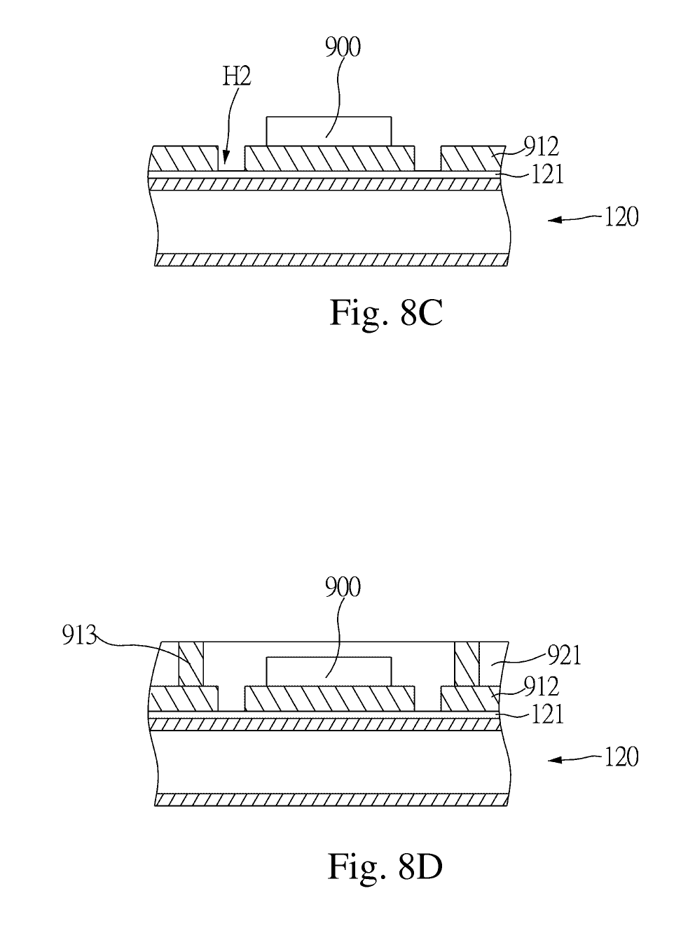

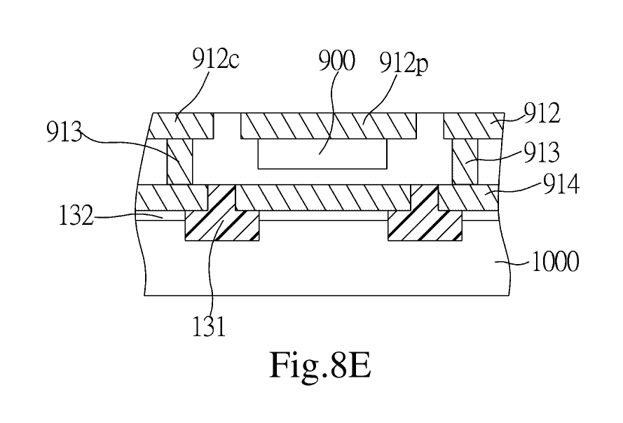

FIG. 8A to FIG. 8E respectively show sectional views of the package carrier in different steps of the manufacturing method provided in accordance with another embodiment of the present invention. This embodiment is similar to the previous embodiment described in FIG. 7A to FIG. 7G. For example, the method of manufacturing according to the embodiment also uses the holding substrate 120 and includes the formation of the insulating pattern 131 and the circuit structure including at least two wiring layers. The following mainly describes the difference between this embodiment and the abovementioned embodiment and doesn't describe and illustrate the sameness of both embodiments again.

Referring to FIG. 8A and FIG. 8B, compared with the first wiring layer 812 shown in FIG. 7B, the first wiring layer 912 of the embodiment is formed by subtractive method. Referring to FIG. 8A, the formation of first wiring layer 912 includes providing the conductive layer 110 and the holding substrate 120, and forming a patterned mask M81, such as a developed dry film or a developed photoresist, on the surface 110s of the conductive layer 110.

Referring to FIG. 8A and FIG. 8B, next, etching the conductive layer 110 by the patterned mask M81 is performed to form a first wiring layer 912 having at least one opening H2 exposing the release layer 121. After forming the first wiring layer 912, the patterned mask M81 is removed.

Referring to FIG. 8C, next, an electronic component 900 is mounted on the first wiring layer 912. The electronic component 900 may be the electronic component 410 and mounted on the first wiring layer 912 by wire bonding, flip chip, or soldering. Referring to FIG. 8D, afterwards, a plurality of metal posts 913 is formed on the first wiring layer 912. The formation of the metal post 913 can be the same as the formation of the metal post 813. However, the thickness of the patterned mask (not shown) for forming the metal posts 913 can be greater than the thickness of the second patterned mask M72. Therefore, the length of the metal post 913 can be greater than the length of the metal post 813.

After forming the metal posts 913, a dielectric layer 921 covering the first wiring layer 912 and the metal posts 913 is formed. The dielectric layer 921 is such as a cured prepreg or cured resin and can be formed by applying or lamination. After forming the dielectric layer 921, the dielectric layer 921 is grinded to expose the ends of the metal post 913.

Referring to FIG. 8D and FIG. 8E, next, the second a wiring layer 914 connected to the metal posts 913 is formed on the dielectric layer 921 so that the metal post 913 is electrically connected to the first wiring layer 912 and the second wiring layer 914. The second wiring layer 914 can be formed by the additive method or the subtractive method. In addition, the second wiring layer 914 and the metal posts 913 can be formed by build-up method. So far, a circuit structure including two wiring layers (i.e. the first wiring layer 912 and the second wiring layer 914), a dielectric layer 921, a electronic component 900 and a plurality of metal posts 913 is formed on the holding substrate 120.

It is noted that, in another embodiment, a wiring layer, a dielectric layer 921, and metal posts 913 can be formed on the second wiring layer 914. Thus, the method of FIG. 8A to FIG. 8E also can manufacture a circuit structure including at least three wiring layers. Moreover, the insulating pattern 131 and the bonding material 132 can be formed on the second wiring layer 914 in sequence after forming the circuit structure.

Next, a supporting board 1000 is provided, and the insulating pattern 131 in contact with supporting board 1000 is detachably connected to the supporting board 1000. Then, the holding substrate 120 is removed, and the solder mask layer 531 and the protective layer 540 as shown in FIG. 5A can be formed on the first wiring layer 912. Alternatively, the protective layer 140 as shown in FIG. 2D can be formed.

Subsequently, the process as described in FIG. 3B can be performed. That is, at least one electronic component may be mounted on the mounting pad 912p of the first wiring layer 912 and connected to the connecting pad 912c of the first wiring layer 912. Afterwards, a molding layer encapsulating the electronic component is formed. After forming the molding layer, the process as described in FIG. 3C can be performed. That is, the supporting board 1000 is removed, and the dicing is performed to form an electronic package without the supporting board 1000.

Notably, in FIG. 8A to FIG. 8D, the release layer 121 can be replaced by the barrier layer 611 as shown in FIG. 6A. Therefore, during forming the first wiring layer 912, the barrier layer 611 can prevent the metal layer 122 from etchant damaging, and the holding substrate 120 can be removed by etching. Moreover, the holding substrate 520 in FIG. 4A can be used in the abovementioned embodiments as disclosed in FIG. 5A to FIG. 8E, so that two package carriers can be manufactured by a holding substrate 520 in these embodiments, thereby increasing the production.

In summary, compared with the conventional electronic package which has core layer, the electronic package in the instant disclosure has a thinner thickness due to the supporting board. Accordingly, the electronic package can be applied to the thinning development trend of mobile devices, such as smart phones, tablets, personal digital assistants (PDA), laptops, handheld game consoles and so on, and the electronic package can be implemented therein.

Additionally, after the plurality of the package carriers are directly formed on the working panel, the package carriers can be tested to determine whether the package carriers are normal or abnormal. Therefore, the possibility of disposing the electronic component on an abnormal package carrier can be attenuated so as to improve the yield of the electronic package.

The descriptions illustrated supra set forth simply the embodiments of the present invention; however, the characteristics of the present invention are by no means restricted thereto. All changes, alterations, or modifications conveniently considered by those skilled in the art are deemed to be encompassed within the scope of the present invention delineated by the following claims.

What is claimed is:

1. A method of manufacturing a package carrier comprising:
providing a holding substrate and a conductive layer, wherein the conductive layer is formed on the holding substrate;
forming an insulating pattern on the conductive layer, wherein the insulating pattern exposes a portion of the conductive layer;
providing a supporting board;
detachably connecting the insulating pattern to the supporting board, wherein the insulating pattern is in contact with the supporting board;
removing the holding substrate and letting the conductive layer remain after detachably connecting the insulating pattern to the supporting board; and
patterning the conductive layer to form a wiring layer after removing the holding substrate.

2. The method of manufacturing the package carrier according to claim 1, wherein the insulating pattern is a solder mask layer.

3. The method of manufacturing the package carrier according to claim 1 further comprising forming a bonding material on the portion of the conductive layer exposed by the insulating pattern.

4. The method of manufacturing the package carrier according to claim 3, wherein the bonding material is a solder layer, metallic layer or organic solderablilty preservatives (OSP) layer.

5. The method of manufacturing the package carrier according to claim 1, wherein the supporting board has a recess pattern fitting the insulating pattern, and the insulating pattern is deposed in the recess pattern after the insulating pattern is detachably connected to the supporting board.

6. The method of manufacturing the package carrier according to claim 1, wherein the holding substrate includes a main plate and a release layer, and the release layer is interposed between the main plate and the conductive layer.

7. The method of manufacturing the package carrier according to claim 1 further comprising forming a solder mask layer on the wiring layer after the wiring layer is formed.

8. The method of manufacturing the package carrier according to claim 7, wherein the supporting board comprises a metal layer electrically connected to the wiring layer, the method after forming the solder mask layer further comprising:
electrifying the metal layer to electroplate the wiring layer, thereby forming a protective layer, wherein the solder mask layer exposes the protective layer.

9. The method of manufacturing the package carrier according to claim 1 further comprising changing a surface roughness of the wiring layer after the wiring layer is formed.

10. The method of manufacturing the package carrier according to claim 1 comprising:
providing at least two conductive layers, wherein the holding substrate is interposed between the conductive layers;
forming two insulating patterns respectively on the conductive layers;
providing two supporting boards;
detachably connecting the insulating patterns to the supporting boards respectively, wherein the insulating patterns is in contact with the supporting boards respectively;
removing the holding substrate and letting the conductive layers remain after detachably connecting the insulating patterns to the supporting boards; and
patterning the conductive layers to form wiring layers respectively after removing the holding substrate.

11. A method of manufacturing a package carrier comprising:
forming a circuit structure and an insulating pattern on a holding substrate, wherein the insulating pattern is attached to the circuit structure, and the circuit structure is interposed between the insulating pattern and the holding substrate;
providing a supporting board;
detachably connecting the insulating pattern to the supporting board, wherein the insulating pattern is in contact with the supporting board; and
removing the holding substrate and letting the circuit structure remain after detachably connecting the insulating pattern to the supporting board.

12. The method of manufacturing the package carrier according to claim 11, wherein forming the circuit structure comprises:
providing a conductive layer on the holding substrate;
forming a barrier layer on the conductive layer; and
forming at least one wiring layer on the barrier layer, wherein the insulating pattern is formed on the wiring layer.

13. The method of manufacturing the package carrier according to claim 12, wherein the barrier layer and the conductive layer are removed after removing the holding substrate.

14. The method of manufacturing the package carrier according to claim 12, wherein forming the wiring layer comprises forming a seed layer on the barrier layer interposed between the conductive layer and the seed layer; further remove the seed layer after removing the holding substrate.

15. The method of manufacturing the package carrier according to claim 11, wherein forming the circuit structure comprises:
forming a first wiring layer on the holding substrate;
forming a plurality of metal posts on the first wiring layer;
after forming the metal posts, forming a dielectric layer covering the first wiring layer and the metal posts; and
forming a second wiring layer connected to the metal posts on the dielectric layer.

16. A package carrier, comprising:
a circuit structure comprising at least one connecting pad and a mounting pad, wherein the mounting pad is used for mounting an electronic component, and the connecting pad is used for electrically connecting the electronic component; and
an insulating pattern attached to the circuit structure.

17. The package carrier according to claim 16, wherein the circuit structure further comprises:
at least two wiring layers, one of the wiring layers comprising the connecting pad and the mounting pad;
at least one dielectric layer interposed between the wiring layers; and
a plurality of metal posts electrically connected to the wiring layer and arranged in the dielectric layer.

18. The package carrier according to claim 16, wherein the circuit structure is a wiring layer, and the insulating pattern in contact with the wiring layer has an opening exposing the connecting pad.

19. The package carrier according to claim 16 further comprising a supporting board having a recess pattern fitting the insulating pattern, wherein the insulating pattern is detachably connected to the supporting board, and the insulating pattern is disposed in the recess pattern.

20. The package carrier according to claim 19, wherein the supporting board comprises:
a plastic board; and
a metal layer laminated on the plastic board and having the recess pattern, wherein the metal layer is interposed between the insulating pattern and the plastic board.

21. A method of manufacturing an electronic package comprising:
mounting the electronic component on the mounting pad of the package carrier according to claim 19;
forming a molding layer encapsulating the electronic component on the circuit structure; and
removing the supporting board after forming the molding layer.

22. The method of manufacturing the electronic package according to claim 21 further comprising:
dicing the supporting board, the insulating pattern and the circuit structure to form a plurality of strips before mounting the electronic component on the circuit structure, wherein the electronic component is mounted on one of the strips.

23. The method of manufacturing the electronic package according to claim 22 further comprising dicing the strip after removing the supporting board.

24. An electronic package, comprising:
the package carrier according to claim 16;
the electronic component mounted on the mounting pad and electrically connected to at least one connecting pad, wherein the mounting pad and the connecting pad are both interposed between the electronic component and the insulating pattern; and
a molding layer covering the electronic component.

25. The electronic package according to claim 24, wherein the package carrier further comprises a supporting board having a recess pattern fitting the insulating pattern, and the insulating pattern is detachably connected to the supporting board and disposed in the recess pattern.
